(19) United States
(12) Patent Application Publication
(10) Pub. No.: US 2014/0159766 A1
(43) Pub. Date: Jun. 12, 2014

(54) HIGH-FREQUENCY MODULE AND METHOD FOR INSPECTING HIGH-FREQUENCY MODULE

(71) Applicants: Suguru Fujita, Tokyo (JP); Ryosuke Shiozaki, Kanagawa (JP)

(72) Inventors: Suguru Fujita, Tokyo (JP); Ryosuke Shiozaki, Kanagawa (JP)

(73) Assignee: PANASONIC CORPORATION, Osaka (JP)

(21) Appl. No.: 14/130,654

(22) PCT Filed: Aug. 22, 2012
(86) PCT No.: PCT/JP2012/005264

§ 371 Date: Jan. 2, 2014

(30) Foreign Application Priority Data
Aug. 31, 2011 (JP) 2011-189849

(51) Int. Cl. G01R 31/26; H01L 23/66

(52) U.S. Cl. CPC G01R 31/2601; H01L 23/66
USPC 324/762.01; 257/48

(57) ABSTRACT

A high-frequency module includes a high-frequency circuit chip, a wiring board having a wiring unit including connection pads which are flip-chip-connected to input and output terminals of the high-frequency circuit chip via bumps, a measurement circuit element that is disposed on a surface, opposed to the wiring board, of the high-frequency circuit chip and is connected between at least two terminals, connected to connection pads of the wiring unit, of the input and output terminals, or that is disposed on a surface, opposed to the high-frequency circuit chip, of the wiring board and is connected to the connection pads, and a detection conductor that is disposed on the high-frequency circuit chip or the wiring board at such a position as to be opposed to the measurement circuit element.

### TECHNICAL FIELD

The present disclosure relates to a high-frequency module and an inspection method of a high-frequency module and, more particularly, to a high-frequency module in which a high-frequency circuit chip is mounted on a board.

### BACKGROUND ART

In high-frequency modules, the characteristics of a circuit chip vary after flip-chip mounting depending on the bump height of the mounting, as a result of which failures that resulting high-frequency module characteristics do not satisfy a specification occur at a considerable rate. However, to evaluate such modules, it is necessary to use an expensive instrument, possibly resulting in increase in manufacturing cost. It is therefore necessary to provide a technique for rejecting mounting failure products without using an expensive instrument.

In this connection, a prior art method for measuring a mounting state of a high-frequency circuit (IC) chip which is disclosed in Patent document 1 is known. As shown in FIG. 14, in a high-frequency module, after a high-frequency circuit chip 1001 is flip-chip mounted on a base board 1002, a temperature increased by its heating is measured, whereby the number of connection failures is calculated and defective products are rejected. In this method, in practice, a temperature sensor 1003 and a heater 1004 are provided on a base board 1002 and a temperature increase due to energization of the heater 1004 is measured by the temperature sensor 1003, whereby a connection state of the high-frequency circuit chip 1001 on the base board 1002 is inspected.

### PRIOR ART DOCUMENTS

### Patent Documents

Patent document 1: JP-A-2001-217289

### SUMMARY OF THE INVENTION

### Problems to be Solved by the Invention

However, the conventional high-frequency module disclosed in Patent document 1 has the following problems. That is, in Patent document 1, the heater is necessary, a space needs to be secured on the high-frequency circuit module, the incorporation of an extra circuit increases the module size, and increase of the manufacturing cost may be caused.

The present disclosure has been made in the above circumstances, and an object of the disclosure is to provide a high-frequency module and an inspection method of a high-frequency module which make it possible to easily measure a mounting state by detecting positions, relative to each other, of a circuit on a high-frequency circuit chip and a circuit on a wiring board.

### Means for Solving the Problems

This disclosure provides a high-frequency module comprising a high-frequency circuit chip having input and output terminals; a wiring board having a wiring unit including connection pads which are flip-chip-connected to the input and output terminals of the high-frequency circuit chip via bumps; a measurement circuit element which is disposed on a surface, opposed to the wiring board, of the high-frequency circuit chip and connected between at least two terminals, connected to connection pads of the wiring unit, of the input and output terminals of the high-frequency circuit chip, or which is disposed on a surface, opposed to the high-frequency circuit chip, of the wiring board and connected to the connection pads of the wiring board; and a detection conductor disposed on the high-frequency circuit chip or the wiring board at such a position as to be opposed to the measurement circuit element.

The disclosure includes the above high-frequency module as modified so that the measurement circuit element is a spiral inductor.

The disclosure includes the above high-frequency module as modified so that the detection conductor is disposed on a line which connects the connection pads connected to the two terminals.

The disclosure includes the above high-frequency module as modified so that the detection conductor is detachable.

The disclosure includes the above high-frequency module as modified so that the detection conductor is connected to a ground potential.

The disclosure includes the above high-frequency module as modified so that the detection conductor is in a floating state.

The disclosure includes the above high-frequency module as modified so that the high-frequency module comprises an external LCR meter and measures a variation of inductance between the connection pads.

The disclosure also provides an inspection method for inspecting a mounting state of a high-frequency module which includes a high-frequency circuit chip having input and output terminals; a wiring board having a wiring unit including connection pads which are flip-chip-connected to the input and output terminals of the high-frequency circuit chip via bumps; a measurement circuit element which is disposed on a surface, opposed to the wiring board, of the high-frequency circuit chip and connected between at least two terminals, connected to connection pads of the wiring unit, of the input and output terminals of the high-frequency circuit chip, or which is disposed on a surface, opposed to the high-frequency circuit chip, of the wiring board and connected between the connection pads of the wiring board; and a detection conductor disposed on the high-frequency circuit chip or the wiring board at such a position as to be opposed to the measurement circuit element, the inspection method comprising the steps of:

preparing a high-frequency circuit module in which the measurement circuit element is disposed on one of the high-frequency circuit chip and the wiring board and the detection conductor is disposed on the other of the high-frequency circuit chip and the wiring board;

measuring an inductance between the connection pads; and

judging a distance between the input and output terminals and the connection pads.

### Advantages of the Invention

This disclosure makes it possible to judge whether or not a connection state of a high-frequency circuit chip and a wiring board by checking whether or not the interval between the high-frequency circuit chip and the wiring board is within a desirable value range without the need for measuring a characteristic with a high-frequency measuring instrument or measuring dimensions with accuracy on the order of several microns.

### BRIEF DESCRIPTION OF THE DRAWINGS

FIG. 1 (perspective view) illustrates the configuration of a high-frequency module according to a first embodiment of this disclosure.

FIG. 2 is a sectional view showing the configuration of the high-frequency module according to the first embodiment of the disclosure.

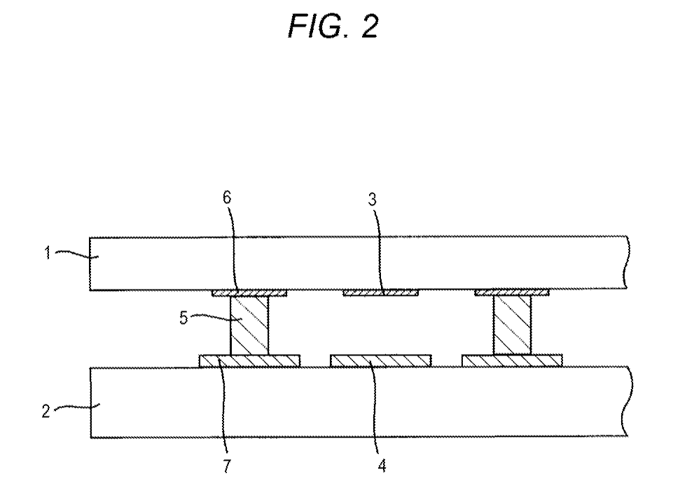

FIG. 3 shows measurements results of the interval between a high-frequency circuit chip and a wiring board used in the high-frequency module according to the first embodiment of the disclosure.

FIG. 4 (perspective view) illustrates the configuration of a high-frequency module according to a second embodiment of the disclosure.

FIG. 5 (perspective view) illustrates the configuration of a high-frequency module according to a third embodiment of the disclosure.

FIG. 6 (seethrough view) illustrating the configuration of a high-frequency module according to a fourth embodiment of the disclosure.

FIGS. 7(a), 7(b), and 7(c) are sectional views corresponding to respective states and show the configuration of the high-frequency module according to the fourth embodiment of the disclosure.

FIG. 8 is a block diagram of a mounting state detection circuit unit of a high-frequency circuit chip of the high-frequency module according to the fourth embodiment of the disclosure.

FIG. 9 illustrates an essential part of a wiring board of the high-frequency module according to the fourth embodiment of the disclosure.

FIG. 10 is a sectional view of an essential part of a high-frequency module according to a modification of the fourth embodiment of the disclosure.

FIG. 11 (seethrough view) illustrating the configuration of a high-frequency module according to a fourth embodiment of the disclosure.

FIGS. 12(a) and 12(b) are sectional views corresponding to respective states and show the configuration of the high-frequency module according to the fifth embodiment of the disclosure.

FIG. 13 illustrates an essential part of a wiring board of the high-frequency module according to the fifth embodiment of the disclosure.

FIG. 14 illustrates an essential part of a conventional high-frequency module.

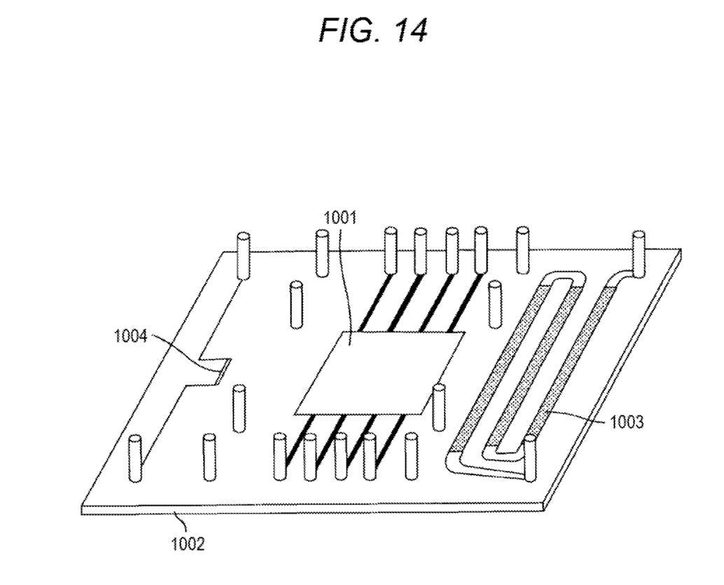

### MODE FOR CARRYING OUT THE INVENTION

High-frequency modules according to embodiments of the present disclosure will be described with reference to the drawings.

### Embodiment 1

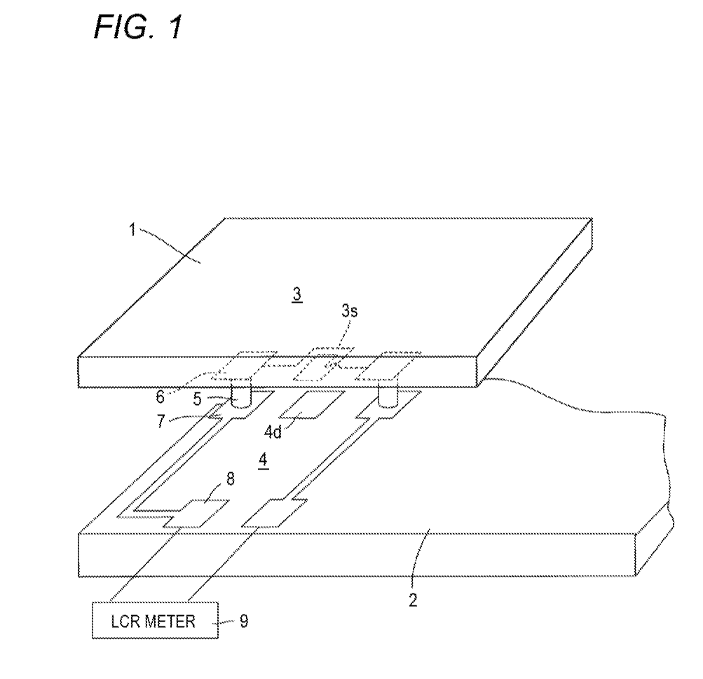

FIG. 1 (perspective view) illustrates the configuration of a high-frequency module according to a first embodiment of the disclosure, and FIG. 1 is a sectional view. This embodiment is directed to a case that a spiral inductor is used as a measurement circuit element.

The high-frequency module is configured so as to include a high-frequency circuit chip 1, a wiring board 2 as a module board on which the high-frequency circuit chip 1 is mounted, a first circuit 3 formed on the high-frequency circuit chip 1, a second circuit 4 formed on the wiring board 2, bumps 5 which conned electrodes of the high-frequency circuit chip 1 and the wiring board 2, input and output terminals (electrodes) 6 on the high-frequency circuit chip 1, and connection pads (electrodes) 7 of the wiring board 2.

For example, the first circuit 3 is formed by using a spiral inductor 3s and the second circuit 4 is formed by using a detection conductor (pad) 4d which has a prescribed size and is connected to a ground potential GND. Although not shown in the figure. GND is provided on the back surface side of the wiring board 2.

The degree of crush of the bumps 5 varies depending on the mounting state, as a result of which the relative positional relationship (e.g., distance) between the spiral inductor 3s and the detection conductor 4d is varied and the characteristic of the spiral inductor 3s is varied.

Output terminals 8 are terminals for measuring a characteristic using an external measuring instrument, for example. The external measuring instrument is an LCR meter 9, for example. The output terminals 8 may form a circuit.

That is, the high-frequency module according to the first embodiment is equipped with the high-frequency circuit chip 1 having the input/output terminals 6 and the wiring board 2 having a wiring unit including the connection pads 7 on which the input and output terminals 6 are flip-chip mounted via the bumps 5.

The first circuit 3 (wiring unit) which is connected to input and output terminals 6 is the spiral inductor 3s which is connected between at least two terminals that are connected to connection pads. The second circuit 4 has the detection conductor 4d which is disposed at such a position as to be opposed to the spiral inductor 3s and is connected to the ground potential.

A variation of the distance between the spiral inductor 3s and the detection conductor 4d which is caused by a variation of the distance between the input and output terminals 6 and the connection pads 7 can be measured by measuring the inductance between the connection pads 7 on the wiring board 2.

The distance between the input and output terminals 6 and the connection pads 7 can be measured by measuring a variation of the inductance between the connection pads 7 due to an inductance variation that is caused by a variation of the distance between the spiral inductor 3s and the detection conductor 4d.

In the high-frequency module, the detection conductor 4d is disposed on a line that connects connection pads 7 that are connected to two respective terminals.

In this disclosure, the two connection pads 7 are connected to two output terminals 8 on the wiring board 2. The external LCR meter 9 is provided which is connected to these output terminals 8, and serves to measure the inductance between the connection pads 7.

Next, an inspection method of the high-frequency module will be described.

First, a variation of the distance between the input and output terminals 6 and the connection pads 7 can be known by detecting an inductance variation that is caused by a variation of the distance between the spiral inductor 3s and the detection conductor 4d by measuring a variation of the inductance between the connection pads 7. It is then judged whether or not the distance is within a normal value range.

Thus, a mounting state can be inspected extremely easily.

According to the invention, an interconnection having a highly accurate inductance value can be formed because the spiral inductor is provided on the side of the high-frequency circuit chip. Therefore, a difference between inductance values before and after mounting can be measured correctly and hence a bump height can be estimated more accurately.

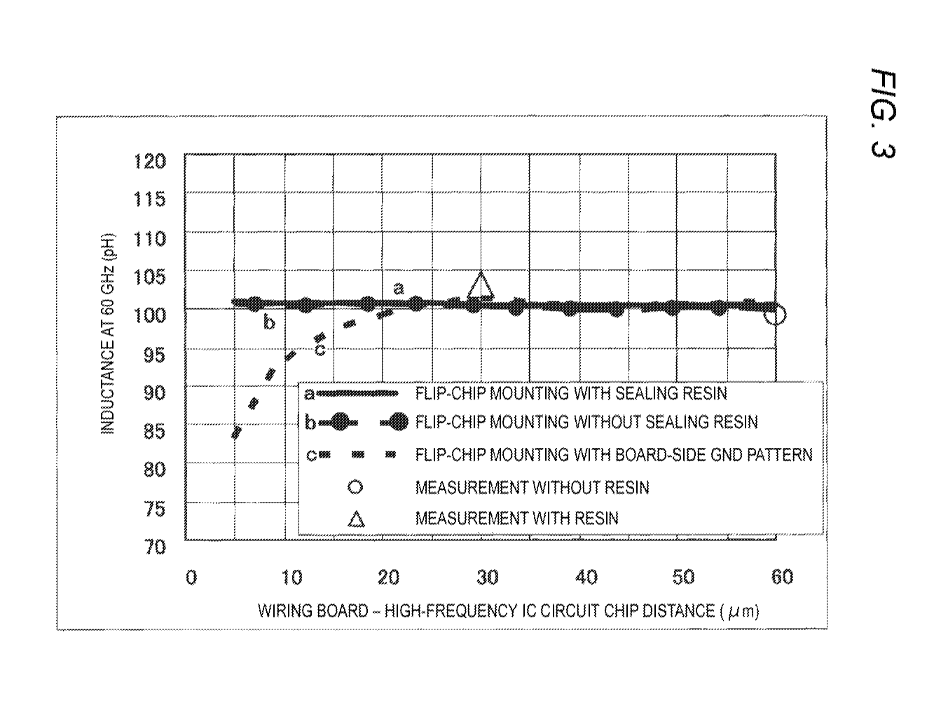

FIG. 3 shows example relationships between the bump height and the characteristic of the spiral inductor. In FIG. 3, the vertical axis represents the inductance and the horizontal axis represents the board-to-high-frequency circuit chip distance (μm). The solid line a indicates a relationship of a case without, the second circuit 4, and the broken line c indicates a relationship of a case with the second circuit 4. The solid line a corresponds to a case that the second circuit 4 is not formed and sealing resin is used, and the chain line b corresponds to a case that the second circuit 4 is not formed and no sealing resin is used. The broken line c corresponds to a case that both of sealing resin and the second circuit 4 are formed.

It is seen that where the second circuit 4 is formed, the inductance vanes as the bump height decreases from 20 μm, which means excessive crush of the bumps can be detected.

Therefore, whether the bump height can be kept larger than or equal to 20 μm can be judged by detecting whether or not the inductance is kept equal to 100 pH.

Although the detection conductor 4d is connected to GND, it may be in a floating state.

In FIG. 3 the solid line and the chain line c almost coincide with each other, from which it is seen that the presence/absence of sealing resin has almost no effect on the inductance. This means that a mounting state can be detected with high accuracy by measuring an inductance value even after resin sealing. Therefore, the inspection according to the embodiment can also be applied to inspection performed after a resin sealing step.

### Embodiment 2

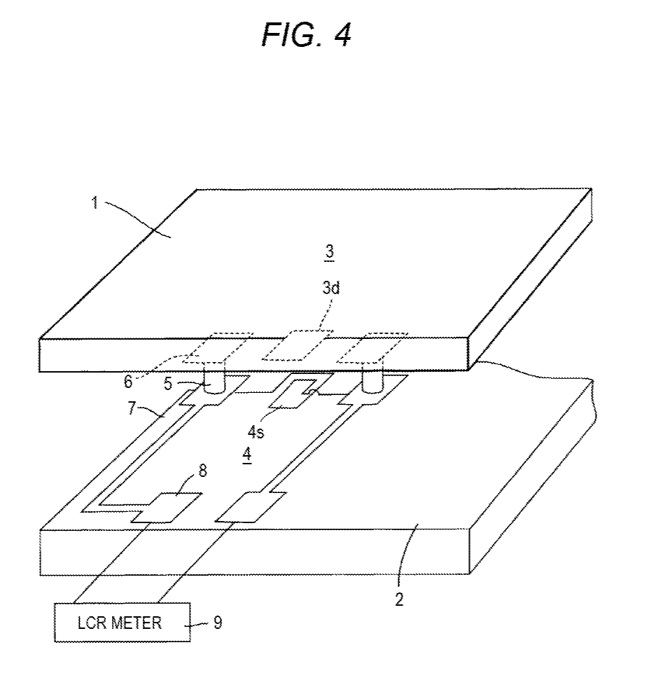

Next, a second embodiment of the disclosure will be described.

Whereas in the high-frequency module according to the first embodiment the spiral inductor 3s is formed on the high-frequency circuit chip 1 and the detection conductor 4d (second circuit 4) is formed on the wiring board 2, in a high-frequency module according to the second embodiment a detection conductor 3d and a spiral inductor 4s are disposed on the high-frequency circuit chip 1 and the wiring board 2, respectively (see a perspective view of FIG. 4).

The second embodiment is the same as the first embodiment in the other respects, and descriptions for those components will be omitted here.

Also in this embodiment, a variation of the distance between the input and output terminals 6 and the connection pads 7 can be known by detecting an inductance variation that is caused by a variation of the distance between the spiral inductor 3s and the detection conductor 4d by measuring a variation of the inductance between the connection pads 7. It is then judged whether or not the distance is within a normal value range. Thus, a mounting state can be inspected extremely easily.

Also with the above configuration, whether a mounting state is good or bad can be judged according to whether the bump height is proper or not.

A modification is possible in which a multilayer board is used as the wiring board, as a result of which the spiral inductor can easily be implemented in a vertical spiral form by means of plural conductor layers that are connected to each other through through-holes. This makes it possible to increase the detection accuracy of the bump height detection. Also in this embodiment, the detection conductor may be in a floating state.

According to this embodiment, a larger spiral inductor can be formed because the spiral inductor 4s is formed on the side of the wiring board. This makes it possible to measure an inductance difference at low frequencies and hence to construct an inspection system using a measuring instrument that is lower in price.

### Embodiment 3

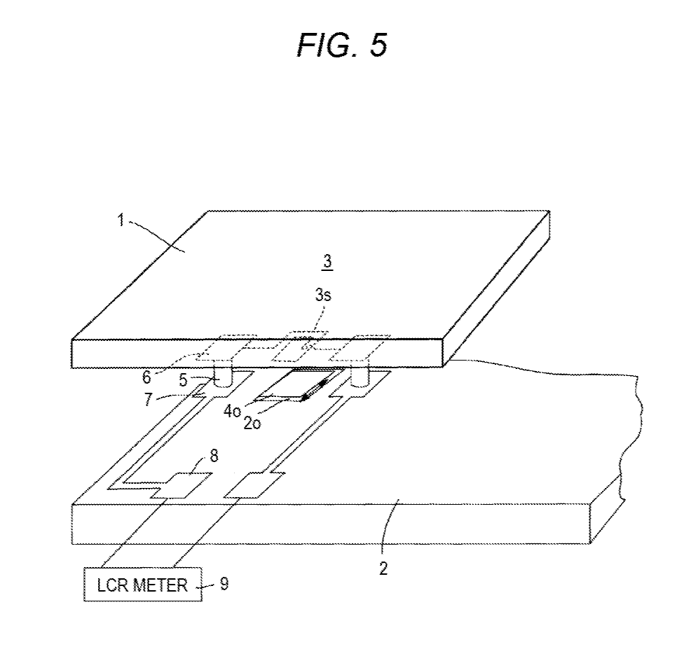

Next, a third embodiment of the disclosure will be described. Whereas in the first and second embodiments the detection conductor is formed on the high-frequency circuit chip 1 or the wiring board 2, as shown in FIG. 5 it may be a detachable external conductor 4o.

An external conductor attachment portion 2o is formed on the wiring board 2 in advance and the external conductor 4o is placed on the external conductor attachment portion 2o. The distance between the high-frequency circuit chip 1 and the wiring board is measured and a bump height is detected in the same manner as in the first and second embodiments. The other components are the same as in the high-frequency module according to the first embodiment and hence will not be described here.

That is, the high-frequency module according to the first embodiment is equipped with the high-frequency circuit chip 1 having the input and output terminals 6 and the wiring board 2 having the wiring unit which includes the connection pads 7 to which the input and output terminals 6 are flip-chip-connected via the bumps 5.

The first circuit 3 (wiring unit) which is connected to input and output terminals 6 is the spiral inductor 3s which is connected between at least two terminals that are connected to connection pads. The external conductor 4o (second circuit) is disposed at such a position as to be opposed to the spiral inductor 3s and is connected to the ground potential in a detachable manner.

A variation of the distance between the input and output terminals 6 and the connection pads 7 that is caused by a variation of the distance between the spiral inductor 3s and the external conductor 4o can be measured by measuring the inductance between the connection pads 7 on the wiring board 2.

That is, the height of the bumps 5 is measured by detecting a variation of the inductance due to the distance between the surface of the external conductor 4o and the spiral inductor 3s.

In the high-frequency module, the external conductor 4o is placed on the external conductor attachment portion 20 which is disposed on a line that connects connection pads 7 that are connected to two respective terminals on the wiring board 2. After the external conductor 4o is placed on the external conductor attachment portion 2o, a bump height is measured by measuring the inductance between the connection pads 7 on the wiring board 2. If a bump height need not be measured, the external conductor 4o is removed. Although the surface of the external conductor attachment portion is required to be high in flatness, this does not affect the other circuit characteristics because the external conductor 4o is removed when a bump height is not measured.

In this disclosure, it is desirable that the external LCR meter 9 which is connected to the output terminals 8 on the wiring board 2 be configured so as to be able to house the external conductor 4o.

Although the first to third embodiments employ the spiral inductor as a measurement circuit element, the measurement circuit element is not limited to a spiral inductor and may be another kind of circuit element such as an inductor or a resistor.

### Embodiment 4

Next, a fourth embodiment of the disclosure will be described.

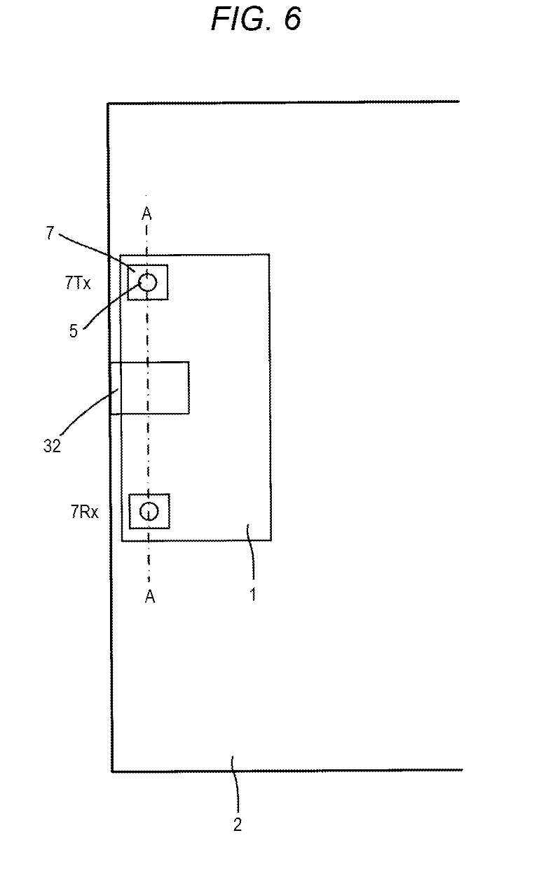

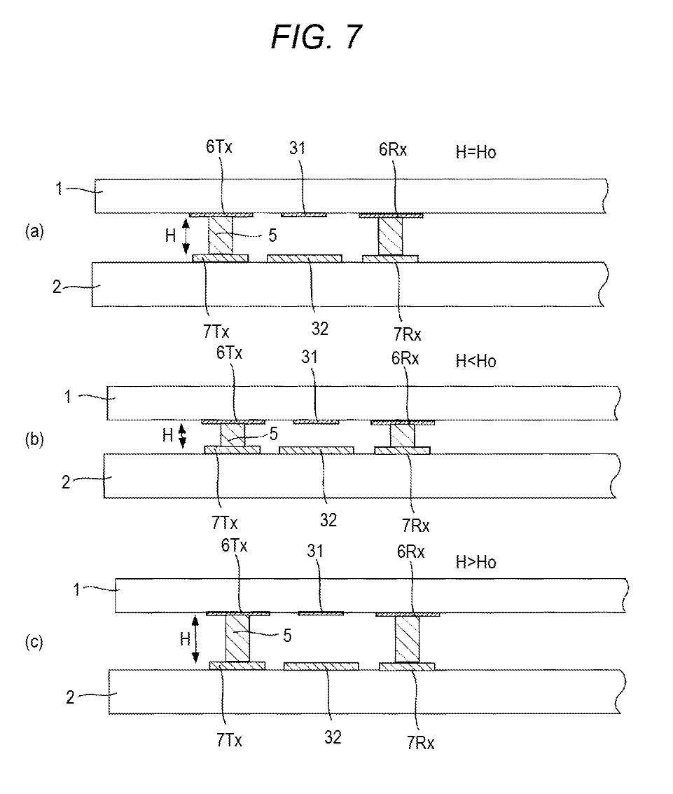

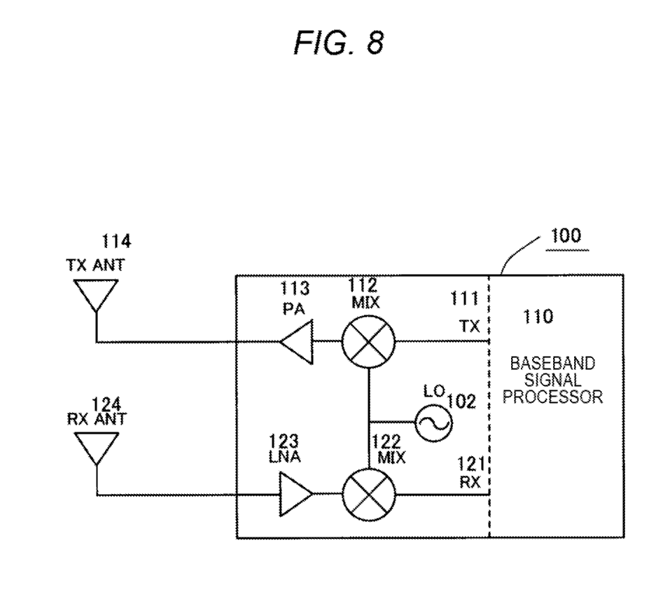

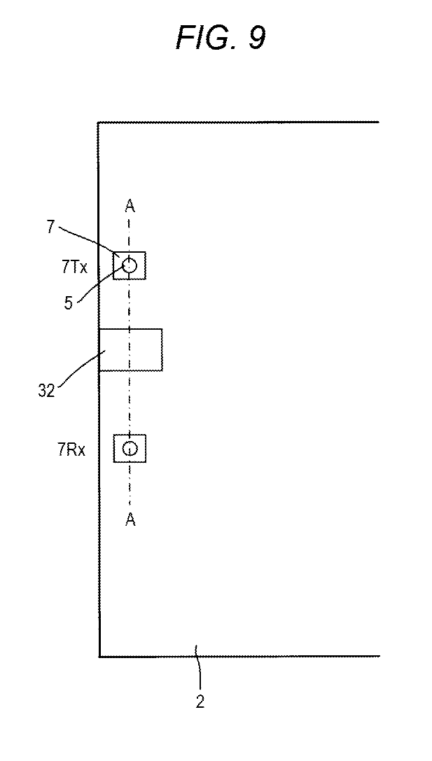

FIG. 6 is a top view showing an essential part of a high-frequency module according to the fourth embodiment of the disclosure. FIGS. 7(a), 7(b), and 7(c) are sectional views corresponding to respective states. FIG. 8 is a block diagram of a mounting state detection circuit unit of a high-frequency circuit chip. FIG. 9 illustrates an essential part of a wiring board. To facilitate understanding, FIG. 6 is drawn as a seethrough view though a high-frequency circuit chip is not transparent. FIGS. 7(a), 7(b), and 7(c) are sectional views taken along line A-A in FIG. 6. Line A-A in FIG. 9 corresponds to that in FIG. 6.

Whereas in the first to third embodiments a bump height is detected using the inductance of the spiral inductor, in this embodiment a mounting state detection circuit unit 100 is integrated in a high-frequency circuit chip 1 which is mounted on a wiring board 2.

In the mounting state detection circuit unit 100, signals that leak from a transmission terminal 6Tx and a reception terminal 6Rx are detected as radiation amounts of signals that are proportional to a bump height by calculating radiation gains using the signals of the transmission system and the reception system.

As a result, bump heights, that is, distances between the transmission terminal 6Tx and the reception terminal 6Rx on the side of the high-frequency circuit chip 1 and connection pads 7Tx and 7Rx on the side of the wiring board 2, can be detected.

FIG. 7(a) shows a case that the high-frequency module according to the embodiment has been formed normally, FIG. 7(b) shows a case that the bumps are short, and FIG. 7(c) shows a case that the bumps are tall. In the high-frequency module according to this embodiment, a mounting state is detected by paying attention to the fact that the positional relationships between the transmission terminal 6Tx and the reception terminal 6Rx on the side of the high-frequency circuit chip 1 and the connection pads 7Tx and 7Rx on the side of the wiring board 2, and hence the radiation gains, vary depending on the mounting state.

In the high-frequency module according to the embodiment, metal patterns as reflective conductors 31 and 32 for signals are formed between the transmission terminal 6Tx and the reception terminal 6Rx on the side of the high-frequency circuit chip 1 and between the connection pads 7Tx and 7Rx on the side of the Wring board 2, respectively, to assist transmission of signals that leak from the transmission terminal 6Tx and the reception terminal 6Rx.

The mounting state detection circuit unit 100 of the high-frequency circuit chip 1 of the high-frequency module according to the embodiment incorporates a baseband signal processor 110 which detects a reception signal Rx of the reception terminal 6Rx using the transmission terminal 6Tx, detects a transmission signal Tx of the transmission terminal 6Tx using the reception terminal 6Rx, and calculates a transmission gain on the basis of the detected signals.

The distance between the transmission terminal 6Tx and the reception terminal 6Rx on the side of the high-frequency circuit chip 1 and between the connection pads 7Tx and 7Rx on the side of the wiring board 2 can be measured on the basis of the calculated radiation gain.

The mounting state detection circuit unit 100 is equipped with the baseband signal processor 110 which generates a mounting state test signal, a transmitter, and a receiver. The transmitter is equipped with a transmission system mixer 112 which converts the mounting state test signal 111 generated by the baseband signal processor 110 into a signal having a carrier frequency using a signal supplied from a high-frequency signal source (LO) 102, a power amplifier (PA) for amplifying the mounting state test signal 111 as converted so as to have the carrier frequency using the signal supplied from a high-frequency signal source 102, and a transmission antenna 114.

On the other hand, the receiver is equipped with a reception antenna 124 for receiving a signal that is transmitted from the transmission antenna 114, a low noise amplifier (LNA) 123 for low-noise-amplifying the signal received by the reception antenna 124, and a reception system mixer 122 for converting the low-noise-amplified reception signal into a baseband signal.

In the high-frequency module, a mounting state test signal 111 generated by the baseband signal processor 110 is input to the transmission system mixer 112, where it is converted into a signal having a carrier frequency using a signal supplied from a high-frequency signal source 102. The resulting signal is input to the transmission antenna 114 via the power amplifier 113.

At the time of reception, a signal received by the reception antenna 124 is low-noise-amplified by the low noise amplifier 123, converted into a baseband signal 121 by the reception system mixer 122, and detected by the baseband signal processor 110.

In the embodiment, a mounting state is detected using transmission signal processing and reception signal processing. Part of a transmission signal that is sent out from the transmission system using the transmission antenna 114 is radiated from, for example, the bump 5 of a circuit chip mounting unit. On the reception side, part of the transmission signal is received by the bump 5 of the circuit chip mounting unit.

A mounting state can be checked by calculating transmission-side and reception-side bump heights, that is, distances between the transmission terminal 6Tx and the reception terminal 6Rx and the connection pads 7Tx and 7Rx on the side of the wiring board 2, by inputting part of a transmission signal to the baseband signal processor via the low noise amplifier (LNA) and the mixer.

One example distance calculation method is a method of measuring intensity of radio waves transmitted to the reception side. As described above, a reception signal that is input from the reception terminal is frequency-converted into an analog baseband signal by the mixer circuit. The analog baseband signal is converted by an analog-to-digital converter into a digital signal, which is subjected to demodulation processing in the baseband signal processor.

Since the maximum amplitude of a signal that is output from the analog-to-digital converter is employed as intensity of reception radio waves, a distance is calculated on the basis of a numerical value of the maximum amplitude. For example, whether a mounting state is good or bad can be detected easily by measuring, in advance, a relationship between the amplitude and the distance; for example, amplitude values 10 mV and 20 mV correspond to distances 20 μm and 50 μm, respectively.

Although an amplitude value itself may be used for a good/bad judgment, it goes without saying that pieces of distance correlation information may be stored in the baseband signal processor in the form of a template and used as distance values.

How a mounting state is judged good or bad will be described in detail using specific examples of numerical values.

First, part of a transmission signal that is sent out from the transmission system using the transmission antenna 114 is radiated from the bump 5. On the reception side, the bump 5 of the circuit chip mounting unit receives part of the transmission signal. An output signal that has been processed by the low noise amplifier 123, the reception system mixer 122, and the baseband signal processor 110 is measured. Mounting states on the transmission side and the reception side can be checked on the basis of a measurement value.

For example, part of a transmission signal is radiated from the bump 5 of the circuit chip mounting unit. On the reception side, part of the transmission signal is received by the bump 5 of the circuit chip mounting unit. The distances between the transmission terminal 6Tx and the reception terminal 6Rx and the connection pads 7Tx and 7Rx on the side of the wiring board 2 are measured by a resulting radiation gain.

Whether or not the distances are within a normal value range is judged on the basis of the measurement values.

(1) Normal case that the heights H of the respective bumps 5 that are connected to the transmission terminal 6Tx and the reception terminal 6Rx of the high-frequency circuit chip 1 are approximately equal to a proper height H0 (see FIG. 7(a))

For example, the return loss at the transmission end of the power amplifier 113 is more than 6 dB and the return loss at the reception end of the low noise amplifier (LNA) 123 is more than 10 dB. If the transmission return loss (absolute value) is assumed to be, for example, 5 dBm, at the transmission end a loss of −11 dBm occurs at the transmission end (power is not transmitted to the transmission antenna 114 due to reflection). The power radiated from the end of the bump 5 depends on the shape of the mounting unit. If the radiation gain (absolute value) is assumed to be, for example, −20 dBi, −51 dBm is transmitted to the reception side.

(2) Case that the heights H of the respective bumps 5 that are connected to the transmission terminal 6Tx and the reception terminal 6Rx of the high-frequency circuit chip 1 are smaller than the proper height H0 (see FIG. 7(b))

Basically the same operation is performed as in case (1). When the bump 5 is low ((bump height H)<H0), the radiation area (the area of the side surface of the bump 5) becomes small and hence the radiation gain lowers. If the radiation gain lowers from −20 dBi to, for example, −23 dBi, the power that is transmitted to the reception side changes from −51 dBm to −54 dBm. The fact that the bump is low can be detected from the radiation power difference.

(3) Case that the heights H of the respective bumps 5 that are connected to the transmission terminal 6Tx and the reception terminal 6Rx of the high-frequency circuit chip 1 are larger than the proper height H0 (see FIG. 7(c))

The operation is opposite to that of case (2) (the bump 5 is low). When the bump 5 is tall ((bump height H (H2))>H0), the radiation area becomes large and hence the radiation gain increases. If the radiation gain increases from −20 dBi to, for example, −17 dBi, the power that is transmitted to the reception side changes from −51 dBm to −48 dBm and hence the fact that the bump 5 is tall can be detected.

Although in cases (1)-(3) the height of the bump 5 is judged small or large by comparing it with the proper height H0, it goes without saying that the allowable height range for the bump height 20 μm depends on the design of the communication system. It is known that for, for example, a wavelength of radiation radio waves there exists a radiation element length that maximizes the radiation gain. The bump height of interest of this disclosure is smaller than 1 mm and the free space wavelength is equal to about 5 mm at 60 GHz and about 3.8 mm at 79 GHz. Since the bump height of interest is shorter than λg/2, the radiation gain increases as the bump height becomes larger and decreases as bump height becomes shorter.

(4) Case that no bumps are connected to the transmission terminal 6Tx and the reception terminal 6Rx of the high-frequency circuit chip 1

Whereas cases (1)-(3) are cases of detecting a mounting failure in a range that the bump connection resistances do not vary, case (4) is direct to a case that bumps are even not connected or bumps are connected but their connection resistances vary.

First, in a state that no bump is connected on the transmission side (a mounting failure is included), a large part of a transmission signal that is supplied from the power amplifier 113 is reflected in the mounting unit and radiated because the bump is tall and hence the area of the reflective conductor is large. For example, the radiation gain becomes −10 dBi and the power that is transmitted to the reception side changes from −51 dBm to −41 dBm. Thus, the non-connection state (a mounting failure is included) of the transmission side can be detected.

Conversely, in a state that no bump is connected on the reception-side terminal (a case of a mounting failure is included), the radiation gain lowers due to unmatching in the reception-side mounting unit, to −30 dBi, for example. And the transmitted power changes from −51 dBm to −61 dBm. Thus, the non-connection state (a mounting failure is included) of the reception side can be detected.

The metal patterns as the reflective conductors 31 and 32 are disposed on the side of the high-frequency circuit chip 1 and on the side of the wiring board 2, respectively, to allow radio waves radiated from the bump 5 connected to the transmission terminal 6Tx to travel to the reception side efficiently. Disposing such a metal plate on only one of the high-frequency circuit chip 1 side or the wiring board 2 side is still effective.

Floating the reflective conductors 31 and 32 can suppress their influences to the other circuits. Furthermore, disposing the signal pads of the input and output terminals on the transmission side and the reception side adjacent or close to each other is effective in efficient traveling.

Setting deviations between the bumps 5 connected to the transmission terminal 6Tx for a transmission signal and the reception terminal 6Rx for a reception signal and the other pads provided between them is effective in efficient traveling of a signal because the positions of the bumps connected to the other pads are also deviated. This is because the bumps 5 connected to the transmission terminal and the reception terminal of the mounting state detection circuit unit 100 can be seen from each other.

It desirable that the reflective conductor 32 (conductor member) be formed on the wiring board 2 on the line that connects the bumps 5 that are formed on the connection pads 7Tx and 7Rx and connected to the transmission terminal 6Tx and the reception terminal 6Rx, respectively. This structure makes it possible to increase the signal reflectivity more efficiently and hence increase the detection accuracy.

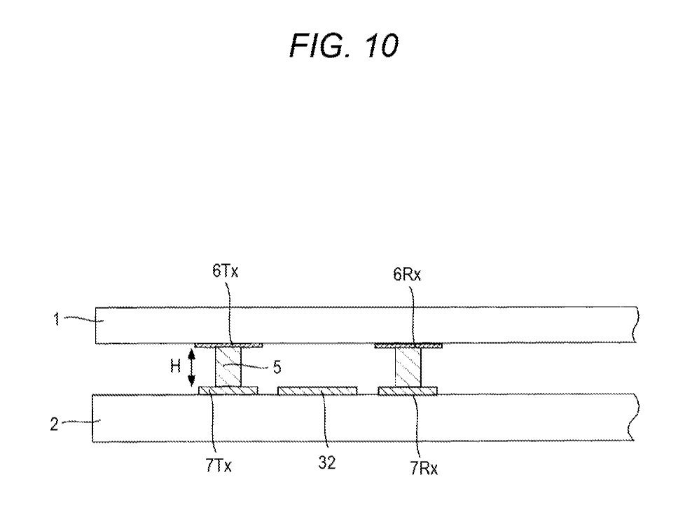

Although in the above embodiment the reflective conductors 31 and 32 are formed on both surfaces of the high-frequency circuit chip 1 and the mounting wiring board 2, a reflective conductor may be formed only on the mounting board side as shown in FIG. 10.

### Embodiment 5

Next, a fifth embodiment of the disclosure will be described.

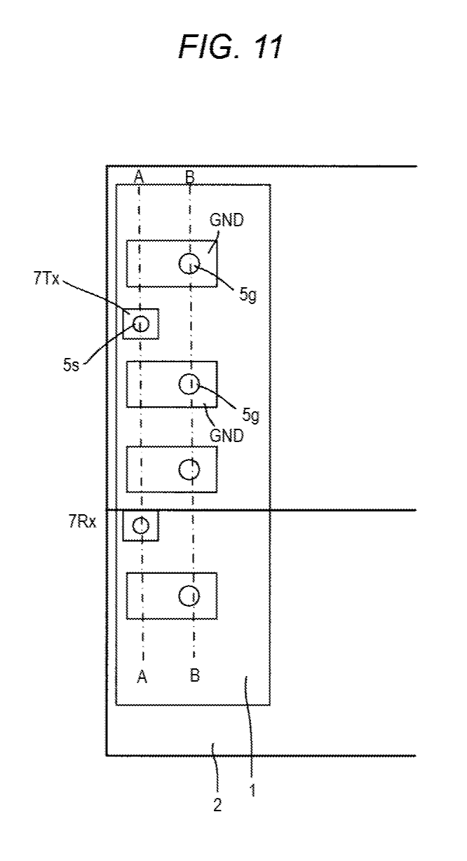

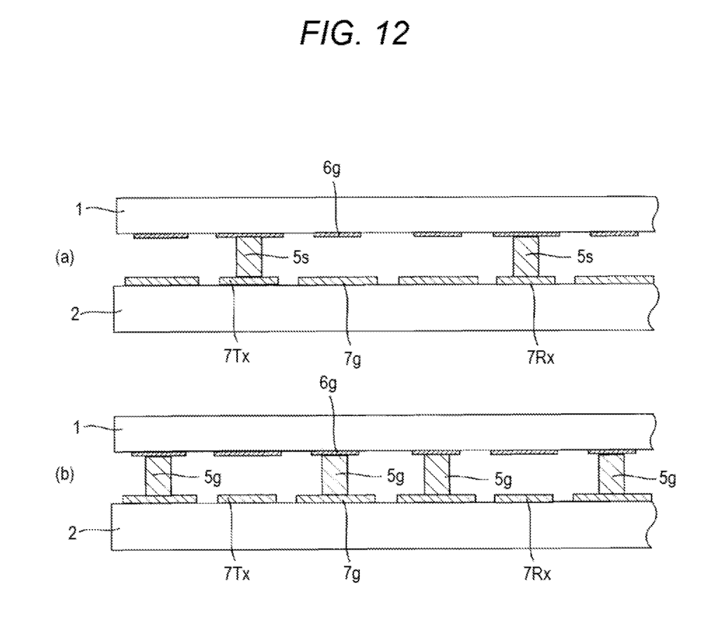

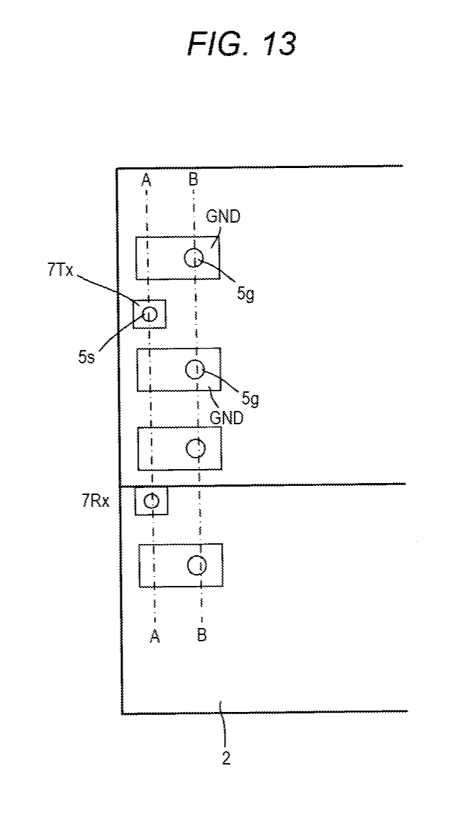

FIG. 11 is a top view of an essential part of a high-frequency module according to the fifth embodiment of the disclosure. FIG. 12(a) is a sectional view taken along line A-A in FIG. 11, and FIG. 12(b) is a sectional view taken along line B-B in FIG. 11. FIG. 13 illustrates an essential part of a wiring board. To facilitate understanding, FIG. 11 is drawn as a seethrough view though a high-frequency circuit chip is not transparent. Line A-A in FIG. 13 corresponds to that in FIG. 11.

In this embodiment, a coplanar wiring structure in which ground lines are formed on the two respective sides of each signal line so as to contain the latter is formed in a wiring unit of a wiring board 2. Ground bumps 5g on respective ground connection pads 7g which are connected to the respective ground lines are formed in regions that are not on a line connecting bumps 5s that are formed on connection pads 7Tx and 7Rx and connected to a transmission terminal 6Tx and a reception terminal 6Rx of a high-frequency circuit chip 1, respectively.

In this embodiment, the ground bumps 5g and the bumps 5s on the connection pads 7Tx and 7Rx have different distances from the chip edge. As a result, the bump 5s on the connection pad 7Tx and the bump 5s on the connection pad 7Rx can be seen from each other.

In this embodiment, as in the fourth embodiment, a mounting state detection circuit unit 100 is integrated in a high-frequency circuit chip 1 which is mounted on the wiring board 2. In the mounting state detection circuit unit 100, radiation gains are calculated using signals of the transmission system and the reception system. As a result, bump heights can be detected by measuring distances between the transmission terminal 6Tx and the reception terminal 6Rx on the side of the high-frequency circuit chip 1 and the connection pads 7Tx and 7Rx on the side of the wiring board 2.

The other components are the same as in the fourth embodiment and hence will not be described here.

The ground bumps 5g are formed inside the bumps 5s which are formed on the connection pads 7Tx and 7Rx.

This is effective in allowing a signal to travel efficiently from a bump. Therefore, a signal coming from a bump can be detected more correctly and whether the bump height is proper or not can be judged.

It is not always necessary to form all ground bumps 5g on the wiring board inside the bumps 5s which are formed on the connection pads 7Tx and 7Rx; it suffices that bumps that would otherwise be located between the bumps 5s formed on the connection pads 7Tx and 7Rx be formed inside the bumps 5s formed on the connection pads 7Tx and 7Rx.

No detailed description has made above of a signal that is sent out and received. However, it suffices that a signal be generated and detected by the baseband signal processor 110. Power intensity of a continuous or burst-like unmodulated signal may be used. Or demodulation performance such as an error rate of a modulated signal may be used.

The above-described embodiments include disclosures in the following modes:

### <Disclosure 1 of High-Frequency Module>

A high-frequency module comprising:

a high-frequency circuit chip having a transmission terminal and a reception terminal; and

a wiring board having a wiring unit including connection pads which are flip-chip-connected to the transmission terminal and the reception terminal of the high-frequency circuit chip via bumps, wherein:

the high-frequency circuit chip or the wiring board comprises a signal processor for calculating a radiation gain on the basis of a detection signal obtained by also detecting a reception signal of the reception terminal or a transmission signal of the transmission terminal with the transmission terminal or the reception terminal; and

the high-frequency module is configured so as to be able to measure a distance between the transmission terminal and the reception terminal and the connection pads on the basis of the radiation gain.

### <Disclosure 2 of High-Frequency Module>

The high-frequency module of disclosure 1, wherein the signal processor is disposed on the high-frequency circuit chip.

### <Disclosure 3 of High-Frequency Module>

The high-frequency module of disclosure 2, wherein a conductor member is disposed on the wiring board on a line that connects bumps on the connection pads that are connected to the transmission terminal and the reception terminal.

### <Disclosure 4 of High-Frequency Module>

The high-frequency module of disclosure 2 or 3, wherein a conductor pattern having a floating state is formed on a surface of the high-frequency circuit chip on a line that connects bumps on the transmission terminal and the reception terminal.

### <Disclosure 5 of High-Frequency Module>

The high-frequency module of disclosure 1, wherein: the wiring unit has a coplanar wiring structure in which ground lines are formed on the two respective sides of each signal line so as to contain the latter; and

ground bumps on ground connection pads that are connected to the ground lines are formed in a region that is not on a line that connects the bumps on the connection pads connected to the transmission terminal and the reception terminal.

### <Disclosure 6 of High-Frequency Module>

The high-frequency module of disclosure 5, wherein the ground bumps are formed inside the bumps and arranged alternately alongside an end line of the high-frequency circuit chip.

### <Disclosure of Method of Inspecting High-Frequency Module>

An inspection method of a high-frequency module for inspecting a high-frequency module which comprises:

a high-frequency circuit chip having a transmission terminal and a reception terminal; and

a wiring board having a wiring unit including connection pads which are flip-chip-connected to the transmission terminal and the reception terminal of the high-frequency circuit chip via bumps, the inspection method comprising:

a step of preparing a high-frequency circuit module in which the high-frequency circuit chip or the wiring board comprises a signal processor for calculating a radiation gain on the basis of a detection signal obtained by also detecting a reception signal of the reception terminal or a transmission signal of the transmission terminal with the transmission terminal or the reception terminal;

a step of measuring a distance between the transmission terminal and the reception terminal and the connection pads on the basis of the radiation gain; and

a judging step of judging whether or not the distance is within a normal value range.

Although the disclosure has been made in detail by referring to the particular embodiments, it is apparent to those skilled in the art that various changes and modifications are possible without departing from the spirit and scope of the disclosure.

The present application is based on Japanese Patent Application No. 2011-189849 filed on Aug. 31, 2011, the disclosure of which is incorporated herein by reference.

### INDUSTRIAL APPLICABILITY

As described above, this disclosure is highly effective because the disclosure makes it possible to efficiently judge whether a mounting state is good or bad and, in particular, to judge a mounting state of a high-frequency device by performing a measurement after completion of mounting. The disclosure is thus applicable to various kinds of high-frequency devices.

### DESCRIPTION OF SYMBOLS

1: High-frequency circuit chip
2: Wiring board
3: First circuit
3d: Detection conductor
3s: Spiral inductor
4: Second circuit
4d: Detection conductor
4s: Spiral inductor
5: Bump
5g: Ground bump
5s: Bump
6: Input/output terminal (electrode)
6Tx: Transmission terminal
6Rx: Reception terminal
7: Connection pad (electrode)
100: Mounting state detection circuit unit
102: High-frequency signal source
110: Baseband signal processor
111: Mounting state test signal
112: Transmission system mixer
113: Power amplifier
114: Transmission antenna
122: Reception system mixer
123: Low noise amplifier
124: Reception antenna
1001: High-frequency circuit chip
1002: Base board
1003: Temperature sensor
1004: Heater

1. A high-frequency module comprising:
a high-frequency circuit chip having input and output terminals;
a wiring board having a wiring unit including connection pads which are flip-chip-connected to the input and output terminals of the high-frequency circuit chip via bumps;
a measurement circuit element that is disposed on a surface, opposed to the wiring board, of the high-frequency circuit chip and is connected between at least two terminals, connected to connection pads of the wiring unit, of the input and output terminals of the high-frequency circuit chip, or that is disposed on a surface, opposed to the high-frequency circuit chip, of the wiring board and is connected to the connection pads of the wiring board; and
a detection conductor that is disposed on the high-frequency circuit chip or the wiring board at such a position as to be opposed to the measurement circuit element.

2. The high-frequency module according to claim 1, wherein the measurement circuit element is a spiral inductor.

3. The high-frequency module according to claim 2, wherein the detection conductor is disposed on a line which connects the connection pads connected to the two terminals.

4. The high-frequency module according to claim 1, wherein the detection conductor is detachable.

5. The high-frequency module according to claim 1, wherein the detection conductor is connected to a ground potential.

6. The high-frequency module according to claim 1, wherein the detection conductor is in a floating state.

7. The high-frequency module according to claim 1, comprising an external LCR meter,
wherein the external LCR meter measures a variation of inductance between the connection pads.

8. An inspection method for inspecting a mounting state of a high-frequency module including a high-frequency circuit chip having input and output terminals, a wiring board having a wiring unit including connection pads which are flip-chip-connected to the input and output terminals of the high-frequency circuit chip via bumps, a measurement circuit element that is disposed on a surface, opposed to the wiring board, of the high-frequency circuit chip and is connected between at least two terminals, connected to connection pads of the wiring unit, of the input and output terminals of the high-frequency circuit chip, or that is disposed on a surface, opposed to the high-frequency circuit chip, of the wiring board and is connected to the connection pads of the wiring board, and a detection conductor that is disposed on the high-frequency circuit chip or the wiring board at such a position as to be opposed to the measurement circuit element, the inspection method comprising the steps of:
preparing a high-frequency circuit module in which the measurement circuit element is disposed on one of the high-frequency circuit chip and the wiring board and the detection conductor is disposed on the other of the high-frequency circuit chip and the wiring board;
measuring an inductance between the connection pads; and
judging a distance between the input and output terminals and the connection pads using the measured inductance.
